(19) United States
(12) Patent Application Publication
(10) Pub. No.: US 2014/0159146 A1
(43) Pub. Date: Jun. 12, 2014

(54) TRENCH GATE TRANSISTOR AND METHOD OF FABRICATING SAME

(71) Applicants: Peilin Wang, BEIJING (CN); EDOUARD DE FRESART, TEMPE, AZ (US); WENYI LI, BEIJING (CN)

(72) Inventors: Peilin Wang, BEIJING (CN); EDOUARD DE FRESART, TEMPE, AZ (US); WENYI LI, BEIJING (CN)

(21) Appl. No.: 14/072,763

(22) Filed: Nov. 5, 2013

(30) Foreign Application Priority Data
Dec. 10, 2012 (CN) 201210529697.2

(51) Int. Cl. H01L 29/78; H01L 29/66

(52) U.S. Cl. CPC H01L 29/7802; H01L 29/66734
USPC 257/330; 438/270

(57) ABSTRACT

A trench gate transistor is formed from a semiconductor substrate with its upper surface covered in an oxide dielectric layer. The trench gate transistor has a drain region, a body region, source region and a trench lined with a gate insulator that electrically insulates a conductive gate electrode formed in the trench from the body region. The body region has a sloping upper surface that extends away from the trench towards the drain region. The sloping upper surface is formed by exposing the oxide dielectric layer to an oxidized atmosphere, through an opening in a mask, so as to form a dielectric region. The dielectric region includes the oxide dielectric layer and a sacrificial area of the semiconductor substrate.

### BACKGROUND OF THE INVENTION

The present invention relates to integrated circuits and, more particularly, to a trench gate transistor and a method of fabricating a trench gate transistor.

A power transistor such as a trench gate Metal Oxide Semiconductor Field Effect Transistor (MOSFET) has an insulated gate located in a trench or cavity with a source region and drain region separated by a doped body region. The gate is insulated typically with a dielectric layer that lines walls of the trench and a conductive source terminal is deposited or formed over the source region and doped body region. When the gate is appropriately biased, a conductive channel is created in the doped body region to allow a drain to source current to flow from the drain region through the conductive channel and to the source region.

Two desirable characteristics of trench gate MOSFETs and other similar transistors are relatively low overall electrical resistance and relatively high Unclamped Inductive Switching (UIS) characteristics. In order to achieve the above characteristics it is useful to reduce the maximum length of the doped body region between the conductive source terminal and the drain region. This length can be reduced by the additional fabricating step of etching the doped body region, which leads to additional fabricating overhead. Thus, it would be advantageous if there was a way to fabricate a trench gate MOSFET that avoided such additional overhead.

### BRIEF DESCRIPTION OF THE DRAWINGS

The invention, together with objects and advantages thereof, may best be understood by reference to the following description of preferred embodiments together with the accompanying drawings in which:

FIG. 1 illustrates a simplified schematic cross-sectional view of a trench gate MOSFET according to the prior art;

FIG. 2 illustrates a simplified schematic cross-sectional view of a trench gate MOSFET according an embodiment of the present invention;

FIG. 3 illustrates a simplified cross section of an initial semiconductor substrate structure used to fabricate the trench gate MOSFET of FIG. 2 in accordance with a preferred embodiment of the present invention;

FIG. 4 illustrates a simplified cross section of a selectively oxidized semiconductor substrate structure that is formed from the substrate structure of FIG. 3 in accordance with a preferred embodiment of the present invention;

FIG. 5 illustrates a simplified cross section of a trenched semiconductor substrate structure that is formed from the substrate structure of FIG. 4 in accordance with a preferred embodiment of the present invention;

FIG. 6 illustrates a simplified cross section of a dielectric covered trenched semiconductor substrate structure that is formed from the substrate structure of FIG. 5 in accordance with a preferred embodiment of the present invention;

FIG. 7 illustrates a simplified cross section of a modified dielectric covered trenched semiconductor substrate structure that is formed from the substrate structure of FIG. 6 in accordance with a preferred embodiment of the present invention;

FIG. 8 illustrates a simplified cross section of an overfilled trench semiconductor substrate structure that is formed from the substrate structure of FIG. 7 in accordance with a preferred embodiment of the present invention;

FIG. 9 illustrates a simplified cross section of an etched overfill trench semiconductor substrate structure that is formed from the substrate structure of FIG. 8 in accordance with a preferred embodiment of the present invention;

FIG. 10 illustrates a simplified cross section of a further etched trench filled semiconductor substrate structure that is formed from the substrate structure of FIG. 9 in accordance with a preferred embodiment of the present invention;

FIG. 11 illustrates a simplified cross section of an upper contoured dielectric trench filled semiconductor substrate structure that is formed from the substrate structure of FIG. 10 in accordance with a preferred embodiment of the present invention;

FIG. 12 illustrates a simplified cross section of a first implanted dielectric trench filled semiconductor substrate structure that is formed from the substrate structure of FIG. 11 in accordance with a preferred embodiment of the present invention;

FIG. 13 illustrates a simplified cross section of a second implanted dielectric trench filled semiconductor substrate structure that is formed from the substrate structure of FIG. 12 in accordance with a preferred embodiment of the present invention;

FIG. 14 illustrates a simplified cross section of a third implanted dielectric trench filled semiconductor substrate structure that is formed from the substrate structure of FIG. 13 in accordance with a preferred embodiment of the present invention;

FIG. 15 illustrates a simplified cross section of a fully overlaid dielectric trench filled semiconductor substrate structure that is formed from the substrate structure of FIG. 14 in accordance with a preferred embodiment of the present invention;

FIG. 16 illustrates a simplified cross section of a partially overlaid dielectric trench filled semiconductor substrate structure that is formed from the substrate structure of FIG. 15 in accordance with a preferred embodiment of the present invention; and

FIG. 17 is a flow chart illustrating a method of fabricating a trench gate transistor in accordance with a preferred embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practiced. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, method steps and structures that comprises a list of elements does not include only those elements but may include other elements not expressly listed or inherent to such module, circuit, steps or device components. An element or step proceeded by “comprises” does not, without more constraints, preclude the existence of additional identical elements or steps that comprises the element or step.

The terms “first,” “second,” “third,” “fourth,” “top,” “bottom,” “upper,” “lower,” and the like in the description and the claims, if any, may be used for distinguishing between somewhat similar elements and/or fabricating steps and not necessarily for describing a particular spatial arrangement or sequence or chronological order. It is to be understood that the terms so used are interchangeable under appropriate circumstances such that embodiments of the invention described herein are, for example, capable of operation or construction in sequences, orientations and arrangements other than those illustrated or otherwise described herein.

The terms “substrate” and “semiconductor substrate” is intended to include any type of semiconductor containing substrate, whether single crystal or polycrystalline or amorphous, and whether layered or homogeneous, as for example and not intended to be limiting, semiconductor-on-insulator (SOI) substrates and insulator on semiconductor (IOS) substrates.

The terms metal-oxide-semiconductor (MOS) and field-effect-transistor (FET), and the combination “MOSFET” have come into common use in the electronics arts for insulated gate field effect transistors (IGFETs) even though they may use any type of dielectric for the gate insulator and not just oxide insulators, and any type of conductor for the gate electrode not just metals. Accordingly, unless otherwise specifically noted, as used herein, the term “metal” in connection with MOSFETs is intended to include any type of conductor. Non-limiting examples of such conductors are metallic conductors, semi-metal conductors, alloy conductors, doped and un-doped semiconductors, and mixtures and combinations thereof. Similarly, unless otherwise specifically noted, the term “oxide” in connection with MOSFETs is intended to include any type of organic or inorganic dielectric. Non-limiting examples of such dielectrics are oxide dielectrics, nitride dielectric, fluoride dielectrics, plastic materials and other types of inorganic and organic dielectrics as well as mixtures and combinations thereof.

In one embodiment, the present invention provides for a method of fabricating a trench gate transistor, the method includes providing an initial semiconductor substrate structure having a semiconductor substrate with an upper surface covered in an oxide dielectric layer with a mask thereon, wherein the semiconductor substrate is doped with a first type of doped implant. The method also includes a process of exposing the oxide dielectric layer to an oxidized atmosphere through at least one opening in the mask to thereby form a dielectric region comprising the oxide dielectric layer and a sacrificial area of the semiconductor substrate, wherein the dielectric region forms a sloping upper surface on the semiconductor substrate.

The method performs also provides for forming a trench extending through the dielectric region and partly into the semiconductor substrate. A gate insulator and conductive gate electrode are deposited in the trench, the gate insulator providing a dielectric barrier between the conductive gate electrode and semiconductor substrate. Removing the dielectric region to expose the sloping upper surface of the semiconductor substrate is performed as well as doping an area of the semiconductor substrate adjacent to both the trench and sloping upper surface with a second type of doped implant. This doped implant is opposite to the first type of doped implant, and thereby partitions the semiconductor substrate into a body region and a drain region. A process performs doping part of the body region with the first type of doped implant to form a source region that is adjacent to both the trench and sloping upper surface. A source contact is then formed over at least part of both the source region and the sloping surface of the body region to provide the trench gate transistor.

In another embodiment, the present invention provides for a trench gate transistor fabricated from a method comprising providing an initial semiconductor substrate structure having a semiconductor substrate with an upper surface covered in an oxide dielectric layer with a mask thereon, wherein the semiconductor substrate is doped with a first type of doped implant. The method also includes a process of exposing the oxide dielectric layer to an oxidized atmosphere through at least one opening in the mask to thereby form a dielectric region comprising the oxide dielectric layer and a sacrificial area of the semiconductor substrate, wherein the dielectric region forms a sloping upper surface on the semiconductor substrate.

The method performs also provides for forming a trench extending through the dielectric region and partly into the semiconductor substrate. A gate insulator and conductive gate electrode are deposited in the trench, the gate insulator providing a dielectric barrier between the conductive gate electrode and semiconductor substrate. Removing the dielectric region to expose the sloping upper surface of the semiconductor substrate is performed as well as doping an area of the semiconductor substrate adjacent to both the trench and sloping upper surface with a second type of doped implant. This doped implant is opposite to the first type of doped implant, and thereby partitions the semiconductor substrate into a body region and a drain region. A process performs doping part of the body region with the first type of doped implant to form a source region that is adjacent to both the trench and sloping upper surface. A source contact is then formed over at least part of both the source region and the sloping surface of the body region to provide the trench gate transistor.

In a further embodiment, the present invention provides for trench gate transistor formed from a semiconductor substrate with an upper surface covered in an oxide dielectric layer. The trench gate transistor has a drain region, a body region, source region and a trench lined with a gate insulator that electrically insulates a conductive gate electrode formed in the trench from the body region. The body region has a sloping upper surface that extends away from the trench towards the drain region. The sloping upper surface is formed by exposing the oxide dielectric layer to an oxidized atmosphere through at least one opening in a mask thereby forming a dielectric region (such as a LOCOS process or other possible process that form dielectric layers). The dielectric region includes the oxide dielectric layer and a sacrificial area of the semiconductor substrate.

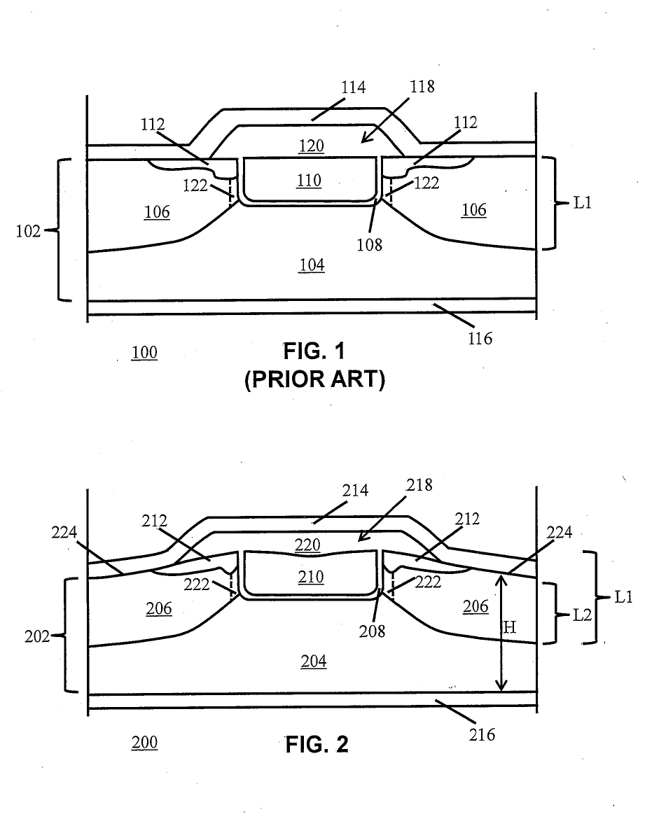

Referring to FIG. 1, a simplified schematic cross-sectional view of a conventional trench gate MOSFET 100 is shown. The trench gate MOSFET 100 comprises a semiconductor substrate 102 having a drain region 104 (e.g., an N type doped region) and body region(s) 106 (e.g., a P type doped region). Located between the combinations of body region 106 and drain region 104 is a trench or cavity 118 lined with dielectric layer 108 that forms part of a gate insulator 120. The gate insulator 120 serves as an insulator for a conductive gate electrode 110 formed in the trench 118 typically from doped polysilicon.

A source region 112 (e.g., an n type doped region) is formed in the body region 106 and the gate insulator 120 overlays both the conductive gate electrode 110 and part of the source region 112. Overlying the gate insulator 120, source region 112 and body region 106 is a metal source contact or lead 114 that acts as a source terminal of the trench gate MOSFET 100 and which is Ohmically coupled to the body region 106 and the source region 112. There is also a metal drain contact 116 Ohmically coupled to the drain region 104 and acts as a drain terminal of the trench MOSFET 100.

In operation, when the conductive gate electrode 110 is appropriately biased, a conductive channel 122 is created in the body region 106, adjacent the dielectric layer 108, so that a drain to source current Ids can flow from the drain region 104 through the conductive channel 122 and to the source region 112. The magnitude of the drain to source current Ids depends upon the magnitude and polarity of the voltage applied to the conductive gate electrode 110 and the magnitude and polarity of the voltage applied across the drain region 104 and source region 112. Also, the maximum length L1 of the body region 106 affects both the overall electrical resistance and the UIS Characteristics of the trench gate MOSFET 100.

FIG. 2 illustrates a simplified schematic cross-sectional view of a trench gate MOSFET 200 according an embodiment of the present invention. The trench gate MOSFET 200 comprises a semiconductor substrate 202 having a drain region 204 (e.g., an N type doped region) and a body region 206 (e.g., a P type doped region). Located between the combinations of body region 206 and drain region 204 is a trench or cavity 218 lined with dielectric layer 208 that forms part of a gate insulator 220. The gate insulator 220 serves as an insulator for a conductive gate electrode 210 formed in the trench 218 typically from doped polysilicon to insulate gate electrode 210 from the body region 206, drain region 204 and source region 212.

A source region 212 (e.g., an n type doped region) is formed in the body region 206 and the gate insulator 220 overlays both the conductive gate electrode 210 and part of the source region 212. Overlying the gate insulator 20, source region 212 and body region 206 is a metal source contact or lead 214 that acts as a source terminal of the trench MOSFET 200 and which is Ohmically coupled to the body region 206 and the source region 212. There is also a metal drain contact 216 Ohmically coupled to the drain region 204 and acts as a drain terminal of the trench MOSFET 200.

In operation, when the conductive gate electrode 210 is appropriately biased, a conductive channel 222 is created in the body region 206, adjacent the dielectric layer 208, so that a drain to source current Ids can flow from the drain region 204 through the conductive channel 222 and to the source region 212. The magnitude of the drain to source current Ids depends upon the magnitude and polarity of the voltage applied to the conductive gate electrode 210 and the magnitude and polarity of the voltage applied across the drain region 204 and source region 212. Also, the maximum length L2 of the body region 206 is less than the maximum length L1 of the of the body region 106 of prior art MOSFET 100 primarily due to a sloping upper surface 224 of the body region 206. More specifically, the sloping upper surface 224 extends away from the trench 218 towards the drain region 204 such that the height H (the effective semiconductor length) of the trench MOSFET 200 decreases as the sloping surface extends away from the trench 218. Hence, the overall electrical resistance of MOSFET 200 is less than that of trench gate MOSFET 100 and trench gate MOSFET 200 can cope with larger UIS currents than trench gate MOSFET 100.

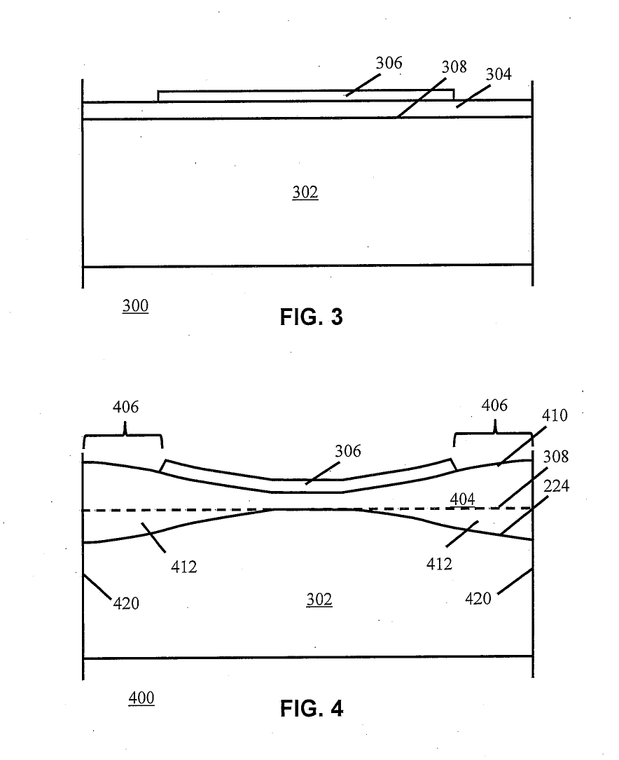

FIGS. 3 to 16 illustrate simplified cross-sectional views of the trench gate MOSFET 200 at various stages of fabricate. Referring specifically to FIG. 3, there is illustrated a simplified cross section of an initial semiconductor substrate structure 300 used to fabricate the trench gate MOSFET 200 in accordance with a preferred embodiment of the present invention. The initial semiconductor substrate structure 300 includes a Silicon substrate 302 with an upper surface 308 upon which is deposited a silicon oxide dielectric layer 304. By way of example and not limitation, the Silicon substrate 302 can be N-type with variable or uniform doping or of P-type doping, depending on whether an NPN or PNP transistor is desired. In this embodiment, because the substrate 302 is silicon then silicon oxide is suitable for the dielectric layer 304. However, other materials may also be used as the dielectric layer 304. On top of the silicon oxide dielectric layer 304 is a hard mask layer 306 of Silicon Nitride. The purpose of hard mask layer 306 is to at least partially protect underlying region(s) of the Silicon substrate 302 during a local oxidation of semiconductor (LOCOS) process performed on the initial semiconductor substrate structure 300.

FIG. 4 shows a simplified cross-section of a selectively oxidized semiconductor substrate structure 400 that is formed from the substrate structure 300 in accordance with a preferred embodiment of the present invention. The selectively oxidized semiconductor substrate structure 400 is the initial semiconductor substrate structure 300 after it has been subjected to LOCOS processing typically with a heated or activated oxygen atmosphere. LOCOS processing is known in the art and after such processing a dielectric region 404 of silicon oxide is formed. The dielectric region 404 is formed from the silicon oxide dielectric layer 304 and a sacrificial area 412 of the Silicon substrate 302 which is converted from silicon to silicon dioxide. As a consequence, the upper surface 308 of the silicon substrate 302 has become the sloping upper surface 224 at regions directly below openings 406 in the hard mask layer 306 and also, to a lesser extent, at regions protected by the hard mask layer 306. As shown, the openings 406 are adjacent to a boundary 420 of the fabricated trench gate MOSFET 200.

The extent of the sloping of the sloping upper surface 224 at regions protected by the hard mask layer 306 is due to lateral diffusion of oxygen during formation of dielectric region 404. Similarly a sloping top surface 410 of the dielectric region 404 results from the LOCOS processing and thus the hard mask layer 306 has been distorted from a planar to a curved layer.

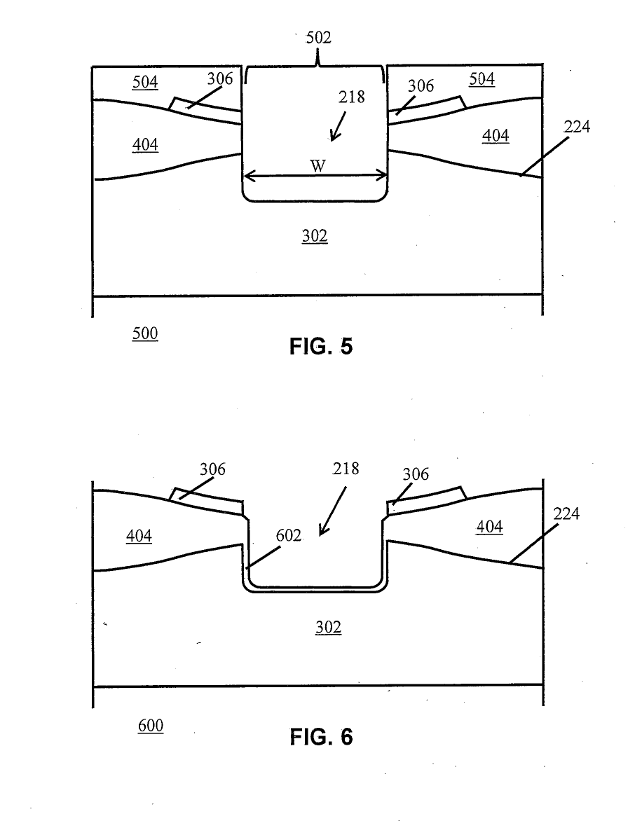

Referring to FIG. 5, there is illustrated a simplified cross section of a trenched semiconductor substrate structure 500 that is formed from the substrate structure 400 in accordance with a preferred embodiment of the present invention. The trenched semiconductor substrate structure 500 is formed by a two-step etching process. The first etching process is a Nitrate etching process that is well known in the art. This first etching process removes a portion of the hard mask layer 306 at the narrowest area of the dielectric region 404 to form a trench etching opening 502. Thereafter a second etching process performs an etching of the trench 218 into both the dielectric region 404 and Silicon substrate 302. As illustrated, a protective mask 504 is positioned over the openings 406 and part of the hard mask layer 306 to thereby direct the etching to only the opening 502 and the underlying dielectric region 404 and Silicon substrate 302.

Plasma etching is a convenient means of etching both the dielectric region 404 and Silicon substrate 302, but other etching techniques may also be used. Reagent gases for accomplishing such plasma etching of dielectric and semiconductor are well known in the art and will depend upon the particular dielectric used for dielectric region 404 and the particular semiconductor material chosen for substrate 302. A width W of trench etch opening 502 in the protective mask 504 primarily determines a width of the trench 218. However, the width of the trench 218 may slightly exceed the width W if an isotropic etch is performed.

Referring to FIG. 6, there is illustrated a simplified cross section of a dielectric covered trenched semiconductor substrate structure 600 formed from the substrate structure 500 in accordance with a preferred embodiment of the present invention. As shown, the protective mask 504 has been removed and a silicon oxide dielectric layer 602 is formed on all surfaces of the trench 218 and thus this silicon oxide dielectric layer 602 essentially becomes integrated with the dielectric region 404. Since in this embodiment the substrate 302 comprises silicon, the dielectric layer 602 is conveniently of silicon oxide, but other dielectric materials may also be used. In a preferred embodiment, a thickness of the silicon oxide dielectric layer 602 is conveniently in the range of about 5 to 150 nm, but thicker and thinner layers may also be used. Thermal oxidation or deposition is a convenient way of forming the silicon oxide dielectric layer 602. However, if required, other techniques well known in the art may also be used.

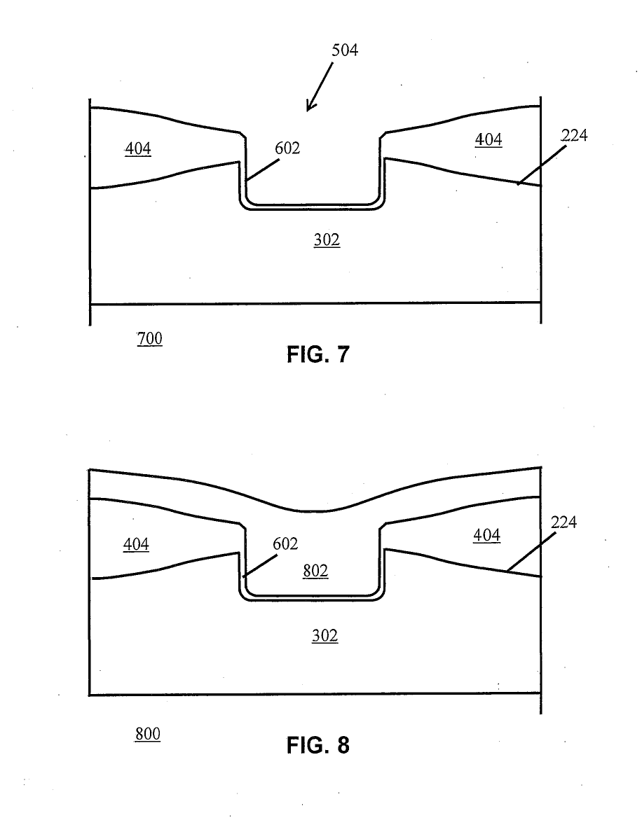

Referring to FIG. 7, a simplified cross-section of a modified dielectric covered trenched semiconductor substrate structure 700 that is formed from the substrate structure 600 in accordance with a preferred embodiment of the present invention is shown. This modified dielectric covered trenched semiconductor substrate structure 700 has had the hard mask layer 306 removed and after which a Nitrate etching process on the exposed hard mask layer 306 is performed.

Referring to FIG. 8, there is illustrated a simplified cross section of an overfilled trench semiconductor substrate structure 800 that is formed from the substrate structure 700 in accordance with a preferred embodiment of the present invention. The overfilled trench semiconductor substrate structure 800 has an overfill (excess) of electrically conductive material 802 deposited in the trench 218 on top of dielectric layer 602 and also on top of the dielectric region 404. The electrically conductive material 802 is typically a polycrystalline semiconductor (e.g., silicon) but other relatively conductive materials may also be used. When the electrically conductive material 802 comprises silicon, it has relatively high conductivity preferably of the same conductivity type as silicon substrate 302, e.g. N type doped material, although other types may also be used, e.g. P type doped material. Chemical Vapor Deposition (CVD) is a suitable technique for forming and depositing the electrically conductive material 802 in the trench 218 on top of dielectric layer 602 and dielectric region 404, although other deposition techniques well known in the art may also be used.

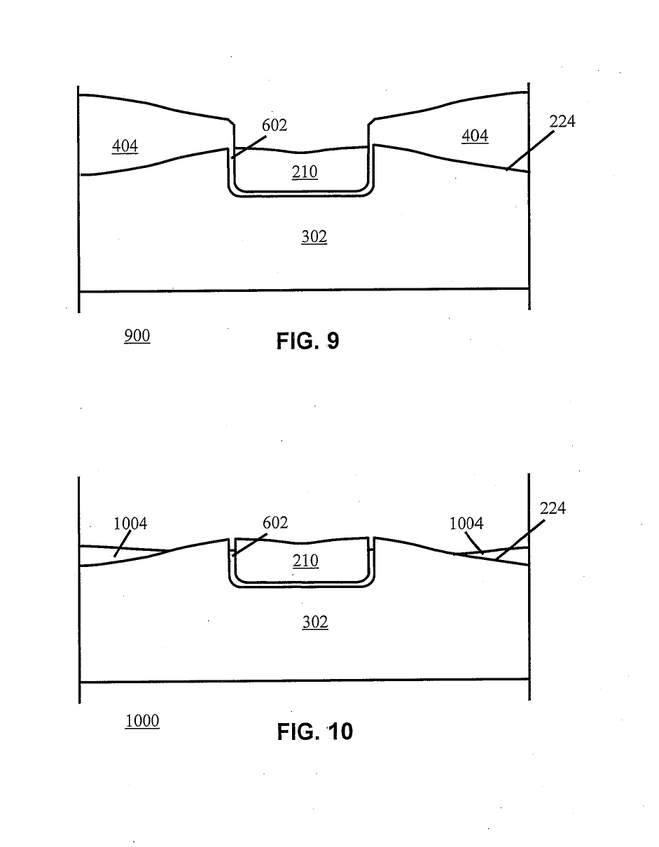

Referring to FIG. 9, there is illustrated a simplified cross section of an etched overfill trench semiconductor substrate structure 900 that is formed from the substrate structure 800 in accordance with a preferred embodiment of the present invention. This etched overfill trench filled semiconductor substrate structure 900 is typically formed by etching the electrically conductive material 802 until all that remains of the electrically conductive material 802 is the material that forms the conductive gate electrode 210 in the trench 218. Plasma anisotropic etching is typically used to etch the electrically conductive material 802. After such etching the conductive gate electrode 210 has an upper surface that is suitably around a highest point of the sloping upper surface 224.

Referring to FIG. 10, there is illustrated a simplified cross section of a further etched trench filled semiconductor substrate structure 1000 formed from the substrate structure 900 in accordance with a preferred embodiment of the present invention. The further etched trench filled semiconductor substrate structure 1000 has been etched to reduce the thickness of the dielectric region 404, typically by isotropic etching, thereby resulting in a reduced dielectric region 1004. Plasma etching is a non-limiting example of a suitable method for removing dielectric region 404 and inherently some of the silicon oxide layer 602 (which is also a dielectric) however, other etching techniques may also be used. By sampling the etchant gas used in plasma etching, the etching process may be conveniently stopped upon detecting the presence of a threshold number of atoms from the silicon substrate 302 in the sampled gas. This therefore indicates that most of the dielectric region 404 has been removed and thereby exposing most of the sloping upper surface 224.

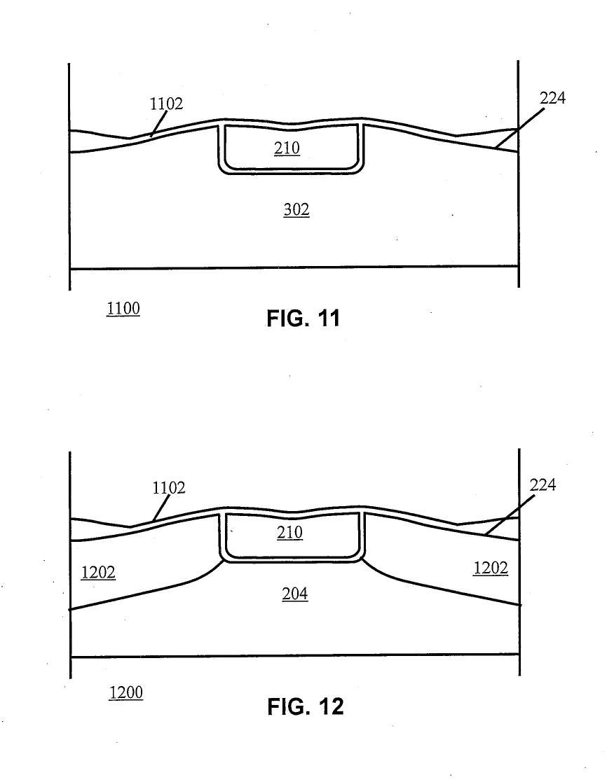

Referring to FIG. 11, there is illustrated a simplified cross section of an upper contoured dielectric trench filled semiconductor substrate structure 1100 formed from the substrate structure 1000 in accordance with a preferred embodiment of the present invention. The upper contoured dielectric trench filled semiconductor substrate structure 1100 has a contoured silicon oxide contoured layer deposited over the sloping upper surface 224 of the silicon substrate 302, the conductive gate electrode 210 and the silicon oxide layer 602. Thus the silicon oxide layer 602 is integrated with the deposited silicon oxide contoured layer and provides an integral silicon oxide contoured dielectric layer 1102 enclosing the conductive gate electrode 210 and covering the sloping upper surface 224 of the silicon substrate 302. Thermal growth is a non-limiting example of a suitable method for forming the silicon oxide contoured dielectric layer 1102 and silicon oxide is a non-limiting example of a suitable material for this dielectric layer but other materials and formation techniques may also be used.

Referring to FIG. 12, there is illustrated a simplified cross section of a first implanted dielectric trench filled semiconductor substrate structure 1200 formed from the substrate structure 1100 in accordance with a preferred embodiment of the present invention. The first implanted dielectric trench filled semiconductor substrate structure 1200 has an implant, which in this embodiment is a P type doped implant, inserted into the silicon substrate 302 and conductive gate electrode 210. As a result of the implant, a body region 1202 (e.g., a P type body region) is formed in the silicon substrate 302 and the silicon substrate 302 is therefore partitioned into the body region 1202 and the drain region 204. Since no mask is illustrated, the conductive gate electrode 210 is also implanted with the P type doped implant however, this is not necessarily required and it can be omitted by suitably positioned overlaying mask. Boron is a non-limiting example of a suitable implant dopant for forming body region 1202 at energies in the range of about 10 to 200 KeV to doses in the range of about 1E12 to 1E15 ions/cm², and multiple doping processes is also possible.

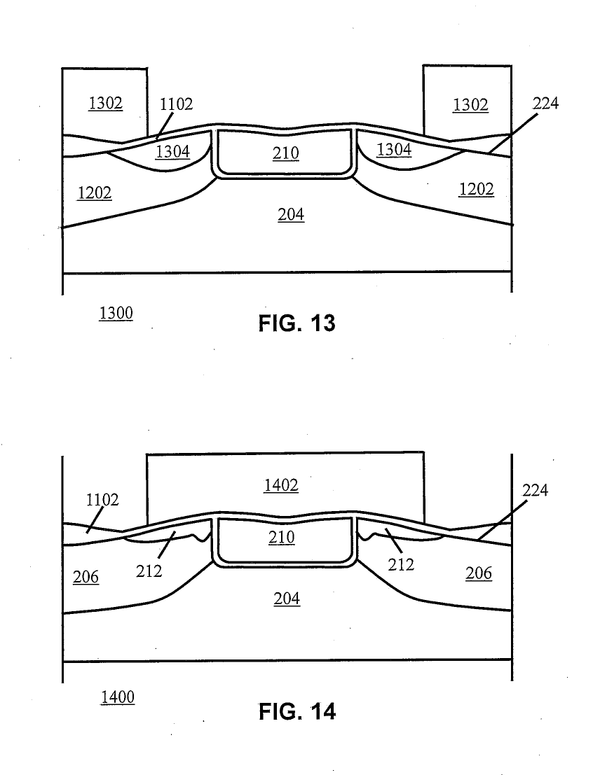

Referring to FIG. 13, there is illustrated a simplified cross section of a second implanted dielectric trench filled semiconductor substrate structure 1300 formed from the substrate structure 1200 in accordance with a preferred embodiment of the present invention. The second implanted dielectric trench filled semiconductor substrate structure 1300 has a second implant, which in this embodiment is an N type doped implant, inserted into the body region 1202 at a location governed by an overlaying mask 1302. This second implant forms an initial source region 1304 and optionally the conductive gate electrode 210 is implanted with the N type doped implant however, a suitably configured overlaying mask 1302 can be used to omit the N type doped implant of the conductive gate electrode 210. Arsenic is a non-limiting example of a suitable dopant for forming the initial source region 1304, but other impurities and combinations of impurities may also be used. The doping of initial source region 1304 is usefully at energies in the range of about 10 to 200 KeV to doses in the range of about 1E14 to 1E16 ions/cm², but higher or lower doses and depth varying doping can also be used.

Referring to FIG. 14, there is illustrated a simplified cross section of a third implanted dielectric trench filled semiconductor substrate structure 1400 formed from the substrate structure 1300 in accordance with a preferred embodiment of the present invention. The third implanted dielectric trench filled semiconductor substrate structure 1400 has a third implant, which in this embodiment is an P type doped implant, inserted into the body region 1202 at a location governed by an overlaying mask 1402 with mask 1302 removed. This P type doped implant is inserted into the body region 1202 and also partly into initial source region 1304 resulting in the body region 206 and source region 212. The purpose of this implant is to facilitate subsequent Ohmic source-metal to body region 206 contact and also to locally counter-dope the initial source region 1304 to form a suitably shaped source region 212.

Boron is a non-limiting example of a suitable dopant, at energies in the range of about 10 to 250 KeV to doses in the range of about 1E12 to 1E16 ions/cm², but larger or smaller doses and energies may also be used, including multiple energy doping. The energy and dose of the previously mentioned implants.

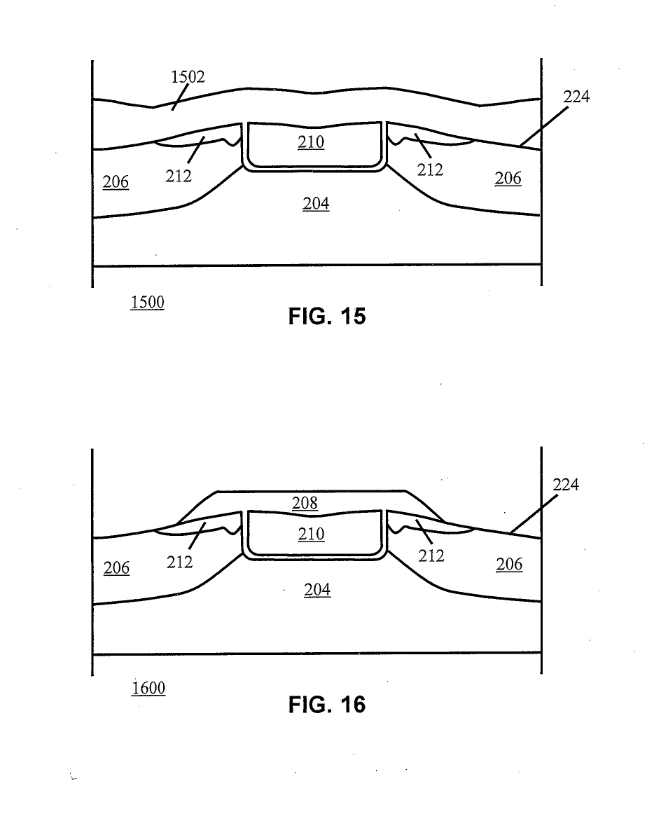

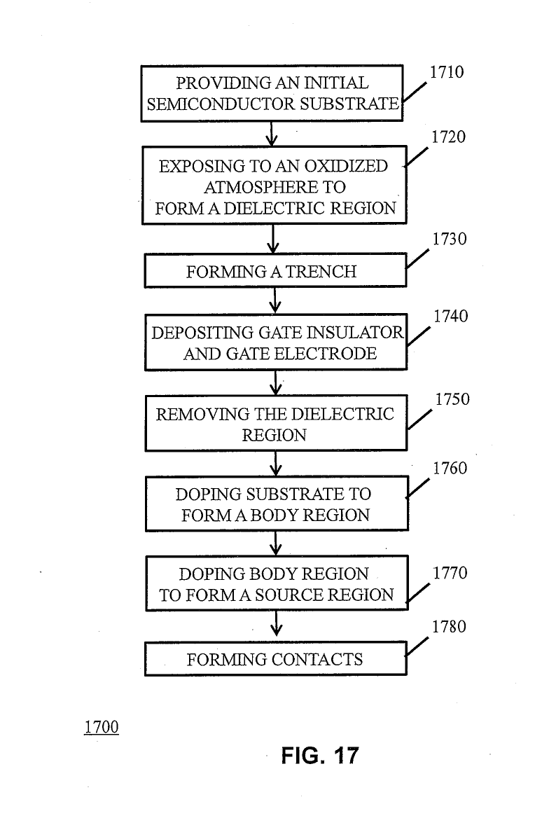

Referring to FIG. 15, there is illustrated a simplified cross section of a fully overlaid dielectric trench filled semiconductor substrate structure 1500 formed from the substrate structure 1400 in accordance with a preferred embodiment of the present invention. The fully overlaid dielectric trench filled semiconductor substrate structure 1500 is formed by removing the mask 1402 and depositing a contoured silicon oxide dielectric layer 1502 over the sloping upper surface 224 of the body region 206, source region 212 and the conductive gate electrode 210. This deposited silicon oxide dielectric layer 1502 includes the silicon oxide contoured dielectric layer 1102 and provides a relatively thick dielectric layer enclosing the conductive gate electrode 210 and covering the sloping upper surface 224. Deposition or oxidation is a non-limiting example of a suitable method for forming the silicon oxide dielectric layer 1502 and silicon oxide is a non-limiting example of a suitable material for this dielectric layer but other materials and formation techniques may also be used.

Referring to FIG. 16, a simplified cross-section of a partially overlaid dielectric trench filled semiconductor substrate structure 1600 formed from the substrate structure 1500 in accordance with a preferred embodiment of the present invention is shown. The partially overlaid dielectric trench filled semiconductor substrate structure 1600 has been subjected to selective etching to reduce and shape the dielectric layer 1502 into the gate dielectric 208 with a photo mask. Plasma etching is a non-limiting example of a suitable method for shaping gate dielectric 208. By sampling the etchant gases used in plasma etching, the etching process may be conveniently stopped upon detecting the presence of a threshold number of atoms of the body region 206 indicating that the sloping upper surface 224 has been reached. After etching, the sloping surface 224 of the body region 206 and part of the source region 212 exposed.

The metal source contact or lead 214 is then deposited or formed over the partially overlaid dielectric trench filled semiconductor substrate structure 1600 thereby making Ohmic electrical contact to the source region 212 and, in this example, also to the body region 206. Also, the drain contact 216 is provided at an under surface of the drain region 204 resulting in the trench gate MOSFET 200. However, this drain contact 216 may be present in the initial semiconductor substrate structure 300.

Referring to FIG. 16, a method 1700 of fabricating a trench gate transistor in accordance with a preferred embodiment of the present invention is illustrated. The method 1700 is particularly suited to, but not necessarily limited to, manufacturing trench gate transistors such as the trench gate MOSFET 200. Accordingly, by way of example only, the method 1700 will be described with reference to FIGS. 2 to 16.

At a providing block 1710, there is provided the initial semiconductor substrate structure 300 with the semiconductor or silicon substrate 302 with the upper surface 308 covered in the oxide dielectric layer 304 and associated mask (hard mask layer 306). This semiconductor substrate is doped with a first type of doped implant of N type material (although a P type material can also be used).

The method 1700, at an exposing block 1720, performs exposing the oxide dielectric layer 304 to an oxidized atmosphere through at least one opening in the hard mask layer 306 to thereby form a dielectric region 404 comprising the oxide dielectric layer 304 and a sacrificial area 412 of the semiconductor substrate 302, wherein the dielectric region forms the sloping upper surface 224 on the semiconductor or silicon substrate 302. The exposing is performed by the LOCOS process and results in the selectively oxidized semiconductor substrate structure 400 in which the opening 406 is adjacent the boundary 420.

At a forming block 1730, there is formed the trench 218 that extends through the dielectric region 404 and partly into the semiconductor or Silicon substrate 302. The process for forming the trench 218 is described above with reference to FIG. 5 and results in the trenched semiconductor substrate structure 500. This trench 218 is formed at a central region of the silicon or semiconductor substrate 302 and the sloping upper surface 224 is a continuous surface enclosing the trench 218.

The method 1700, at a depositing block 1740, deposits the gate insulator 208 and conductive gate electrode 210 in the trench 218. |This gate insulator 208 provides a dielectric barrier between the conductive gate electrode 210 and semiconductor substrate 302. This depositing is explained in more detail with reference to FIGS. 8 to 11 and FIGS. 15 to 16.

At a removing block 1750, the dielectric region 404 is removed to expose the sloping upper surface 224 of the semiconductor substrate 302 and results in the further etched trench filled semiconductor substrate structure 1000.

At a doping block 1760 there is performed a doping of an area of the semiconductor substrate 302 adjacent to both the trench 218 and sloping upper surface 224. This doping is with a second type of doped implant such as a P type material (or alternatively an N type material when the first type of doped implant is a P type material). This is second type of doped implant is opposite to the first type of doped implant, and thereby partitions the semiconductor substrate into the body region 1202 and the drain region 204. After the method performs the process of the doping block 1760, the first implanted dielectric trench filled semiconductor substrate structure 1200 is formed.

At another doping block 1770, there is performed a process of doping part of the body region 1202 with the first type of doped implant to form the initial source region 1304 that is adjacent to both the trench 218 and sloping upper surface 224 resulting in the second implanted dielectric trench filled semiconductor substrate structure 1300. Thereafter a further doping process is performed on the initial source region 1304 with the second type of doped implant to thereby shape the intimal source 1304 region into the source region 212 This further doping process results the third implanted dielectric trench filled semiconductor substrate structure 1400.

The method 1700, at a forming block 1780, deposits or forms a source contact 214 over at least part of both the source region 212 and the sloping surface 224 of the body region to provide the trench gate MOSFET 200. In this regard, the forming may further include depositing or forming the drain contact to the drain region 204. Alternatively, the drain contact 204 may be deposited or formed on the initial semiconductor substrate structure 300.

Advantageously, the present invention provides for a trench gate transistor relatively low overall electrical resistance and relatively high Unclamped Inductive Switching (UIS) Characteristics. This is achieved by reducing the maximum length of the doped body region between the conductive source terminal and the drain region. This length is reduced without the additional fabricating step of etching the doped body region since the LOCOS process has been used to both form a necessary dielectric layer and sloping upper surface 224.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A method of fabricating a trench gate transistor, the method comprising:
providing an initial semiconductor substrate structure having a semiconductor substrate with an upper surface covered in an oxide dielectric layer with a mask thereon, wherein the semiconductor substrate is doped with a first type of doped implant;
exposing the oxide dielectric layer to an oxidized atmosphere through at least one opening in the mask to thereby form a dielectric region comprising the oxide dielectric layer and a sacrificial area of the semiconductor substrate, wherein the dielectric region forms a sloping upper surface on the semiconductor substrate;
forming a trench extending through the dielectric region and partly into the semiconductor substrate;
depositing a gate insulator and conductive gate electrode in the trench, the gate insulator providing a dielectric barrier between the conductive gate electrode and semiconductor substrate;
removing the dielectric region to expose the sloping upper surface of the semiconductor substrate;
doping an area of the semiconductor substrate adjacent to both the trench and sloping upper surface with a second type of doped implant, that is opposite to the first type of doped implant, to thereby partition the semiconductor substrate into a body region and a drain region;
doping part of the body region with the first type of doped implant to form a source region that is adjacent to both the trench and sloping upper surface; and
forming a source contact over at least part of both the source region and the sloping surface of the body region to provide the trench gate transistor.

2. The method of claim 1, wherein the sloping upper surface extends away from the trench towards the drain region.

3. The method of claim 2, wherein the trench is formed at a central region of the semiconductor substrate.

4. The method of claim 3, wherein the exposing is characterized by the at least one opening being adjacent a boundary of the transistor.

5. The method of claim 3, wherein the sloping upper surface is a continuous surface enclosing the trench.

6. The method of claim 2, wherein the exposing is by a LOCOS process.

7. The method of claim 2, wherein the doping part of the body region includes further doping the source region with the second type of doped implant to thereby shape the source region.

8. The method of claim 2, wherein the forming a source contact further includes forming a drain contact to the drain region.

9. The method of claim 2, wherein a drain contact is deposited on the initial semiconductor substrate structure.

10. The method of claim 2, wherein the first type of doped implant is a P type implant and the second type of doped implant is an N type implant.

11. The method of claim 2, wherein the first type of doped implant is an N type implant and the second type of doped implant is a P type implant.

12. A trench gate transistor fabricated from a method comprising:
providing an initial semiconductor substrate structure having a semiconductor substrate with an upper surface covered in an oxide dielectric layer with a mask thereon, wherein the semiconductor substrate is doped with a first type of doped implant;
exposing the oxide dielectric layer to an oxidized atmosphere through at least one opening in the mask to thereby form a dielectric region comprising the oxide dielectric layer and a sacrificial area of the semiconductor substrate, wherein the dielectric region forms a sloping upper surface on the semiconductor substrate;
forming a trench extending through the dielectric region and partly into the semiconductor substrate;
depositing a gate insulator and conductive gate electrode in the trench, the gate insulator providing a dielectric barrier between the conductive gate electrode and semiconductor substrate;
removing the dielectric region to expose the sloping upper surface of the semiconductor substrate;
doping an area of the semiconductor substrate adjacent to both the trench and sloping upper surface with a second type of doped implant, that is opposite to the first type of doped implant, to thereby partition the semiconductor substrate into a body region and a drain region;
doping part of the body region with the first type of doped implant to form a source region that is adjacent to both the trench and sloping upper surface; and
forming a source contact over at least part of both the source region and the sloping surface of the body region.

13. The trench gate transistor of claim 12, wherein the sloping upper surface extends away from the trench towards the drain region.

14. The trench gate transistor of claim 13, wherein the trench is formed at a central region of the semiconductor substrate.

15. The trench gate transistor of claim 13, wherein the sloping upper surface is a continuous surface enclosing the trench.

16. A trench gate transistor formed from a semiconductor substrate with an upper surface covered in an oxide dielectric layer, the trench gate transistor comprising:
a drain region;
a body region;
a source region; and
a trench lined with a gate insulator that electrically insulates a conductive gate electrode formed in the trench from the body region,
wherein the body region has a sloping upper surface that extends away from the trench towards the drain region, and wherein the sloping upper surface is formed by exposing the oxide dielectric layer to an oxidized atmosphere through at least one opening in a mask, thereby forming a dielectric region comprising the oxide dielectric layer and a sacrificial area of the semiconductor substrate.

17. The trench gate transistor of claim 16, wherein the exposing is by a LOCOS process.

18. The trench gate transistor of claim 16, wherein the trench is formed at a central region of the semiconductor substrate.

19. The trench gate transistor of claim 17, wherein the sloping upper surface is a continuous surface enclosing the trench.
